(19) United States
(12) Patent Application Publication
(10) Pub. No.: US 2024/0218192 A1
(43) Pub. Date: Jul. 4, 2024

(54) SUPERSTRATE COMPRISING AN ELECTRICALLY CONDUCTIVE LAYER

(71) Applicant: CANON KABUSHIKI KAISHA, Tokyo (JP)

(72) Inventor: Fen WAN, Austin, TX (US)

(21) Appl. No.: 18/147,496

(22) Filed: Dec. 28, 2022

(51) Int. Cl. C09D 5/24; C09D 7/65; C09D 181/02; C09D 201/04

(52) U.S. Cl. CPC C09D 5/24; C09D 7/65; C09D 181/02; C09D 201/04

(57) ABSTRACT

A superstrate can comprise a core body having a first surface and a second surface, the first surface and the second surface being opposite to each other; an electrically conductive layer directly overlying the first surface of the core body; and a capping layer directly overlying the conductive layer, wherein the core body can have an electrical conductivity of not greater than 10⁻¹⁰ S/m; the conductive layer is metal-free and comprises an electrical conductivity of at least 10⁻⁴ S/m and a UV transparency at 365 nm of at least 80%; and the capping layer includes a fluoropolymer and has a UV transparency at 365 nm of at least 80%. The capping layer can contribute to an increase of the electrical conductivity of the underlying electrically conductive layer.

### FIELD OF THE DISCLOSURE

The present disclosure relates to a superstrate comprising an electrically conductive layer and a capping layer directly overlying the conductive layer, and a method of making the superstrate.

### BACKGROUND

Inkjet Adaptive Planarization (IAP) requires the use of a superstrate with a high flatness of its working surface. The superstrate is typically made from a non-conductive fused silica or other transparent non-metallic materials. An unwanted side effect when separating the superstrate from a cured resist can be the accumulation of electrostatic charges due to an electrochemical potential difference. Such unwanted charges can increase the adhesion between the superstrate and the cured resist and thereby require increased separation forces. The electrostatic charges can also attract particles from the surrounding, which may cause impurities and imprint defects in the resist.

There is a need to eliminate or minimize the forming of electrostatic charges between the superstrate and a cured resist to improve the quality of the formed resist, and to insure a high production throughput.

### SUMMARY

In one embodiment, a superstrate can comprise a core body having a first surface and a second surface, the first surface and the second surface being opposite to each other; an electrically conductive layer directly overlying the first surface of the core body; and a capping layer directly overlying the conductive layer, wherein the core body has an electrical conductivity of not greater than 10⁻¹⁰ S/m; the conductive layer is metal-free and comprises an electrical conductivity of at least 10⁻⁴ S/m and a UV transparency at 365 nm of at least 80%; and the capping layer includes a fluoropolymer and has a UV transparency at 365 nm of at least 80%.

In one aspect of the superstrate, the electrically conductive layer can include an electrically conductive polymer. In a certain aspect, the electrically conductive polymer can include a polyacetylene, a polypyrrole, a polythiophene, a poly(3-alkylthiophene), a polyphenylene sulfide, a polyphenylenevinylene, a polythienylenevinylene, a polyphenylene, or a polyaniline, or any combination thereof. In a particular aspect, the electrically conductive polymer can include a polythiophene, a polyphenylene, or a combination thereof. In a certain particular aspect, the conductive polymer may include poly(3,4-ethylenedioxythiophene) (PEDOT).

In another embodiment of the superstrate, the electrically conductive layer can further include a dopant.

In one aspect, the amount of the dopant can be at least 1 wt % and not greater than 40 wt % based on the total weight of the conductive polymer and the dopant.

In another aspect, the dopant contained in the electrically conductive layer can include an ionic polymer. In a particular aspect, the dopant can include a polystyrene sulfonate.

In a certain aspect of the superstrate, the electrically conductive layer can consist essentially of poly(3,4-ethylenedioxythiophene) (PEDOT) and polystyrene sulfonate (PSS).

In a further embodiment, the capping layer overlying the conductive layer can be an amorphous layer and may have a helium gas permeability of at least 10⁻⁸ cm³·cm/cm²·s·cm Hg.

In one aspect, the fluoropolymer of the capping layer can include the structure of formula (1):

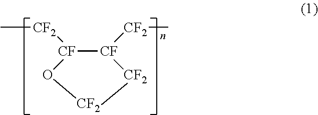

In another aspect of the superstrate, the thickness of the conductive layer can be at least 40 nm and not greater than 1000 nm. In a certain aspect, the thickness of the conductive layer may be at least 50 nm and not greater than 200 nm.

In a further embodiment, the thickness of the capping layer can be at least 20 nm and not greater than 300 nm. In a particular aspect, the thickness of the capping layer may be at least 50 nm and not greater than 150 nm.

In a certain embodiment of the superstrate, the thickness ratio of the thickness of the electrically conductive layer to the thickness of the capping layer can range from 1:1 to 30:1.

In a particular aspect of the superstrate, the electrical conductivity of the electrically conductive layer covered by the capping layer can be at least 14 S/m.

In another embodiment, a method of forming a superstrate can comprise: providing a core body having a first surface and a second surface, the first surface being opposite to the second surface; applying on the first surface of the core body a liquid layer of a coating composition, the coating composition including an electrically conductive polymer and a dopant; solidifying the coating composition to form an electrically conductive layer; applying a protective coating composition on the electrically conductive layer to form a capping layer, the protective coating composition including a fluoropolymer.

In one aspect of the method, the electrically conductive layer can consist essentially of poly(3,4-ethylenedioxythiophene) (PEDOT) and polystyrene sulfonate (PSS).

### BRIEF DESCRIPTION OF THE DRAWINGS

Embodiments are illustrated by way of example and are not limited in the accompanying figure.

FIG. 1 includes a line drawing illustrating a superstrate of the present disclosure according to one embodiment.

FIG. 2 includes a scheme describing a method of forming a superstrate according to one embodiment.

FIG. 3 includes a line drawing illustrating the testing setup for measuring the resistance for determining the electrical conductivity according to one embodiment.

FIG. 4 includes a graph showing linear curves for four different samples of L/A vs. R for determining the electrical conductivity according to embodiments.

FIG. 5 illustrates an apparatus including a superstrate according to one embodiment.

Skilled artisans appreciate that elements in the figures are illustrated for simplicity and clarity and have not necessarily been drawn to scale. For example, the dimensions of some of the elements in the figures may be exaggerated relative to other elements to help improve understanding of embodiments of the invention.

### DETAILED DESCRIPTION

The following description is provided to assist in understanding the teachings disclosed herein and will focus on specific implementations and embodiments of the teachings. This focus is provided to assist in describing the teachings and should not be interpreted as a limitation on the scope or applicability of the teachings.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the imprint and lithography arts.

As used herein, the terms “comprises,” “comprising,” “includes,” “including,” “has,” “having” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus.

As used herein, and unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” are employed to describe elements and components described herein. This is done merely for convenience and to give a general sense of the scope of the invention. This description should be read to include one or at least one and the singular also includes the plural unless it is obvious that it is meant otherwise.

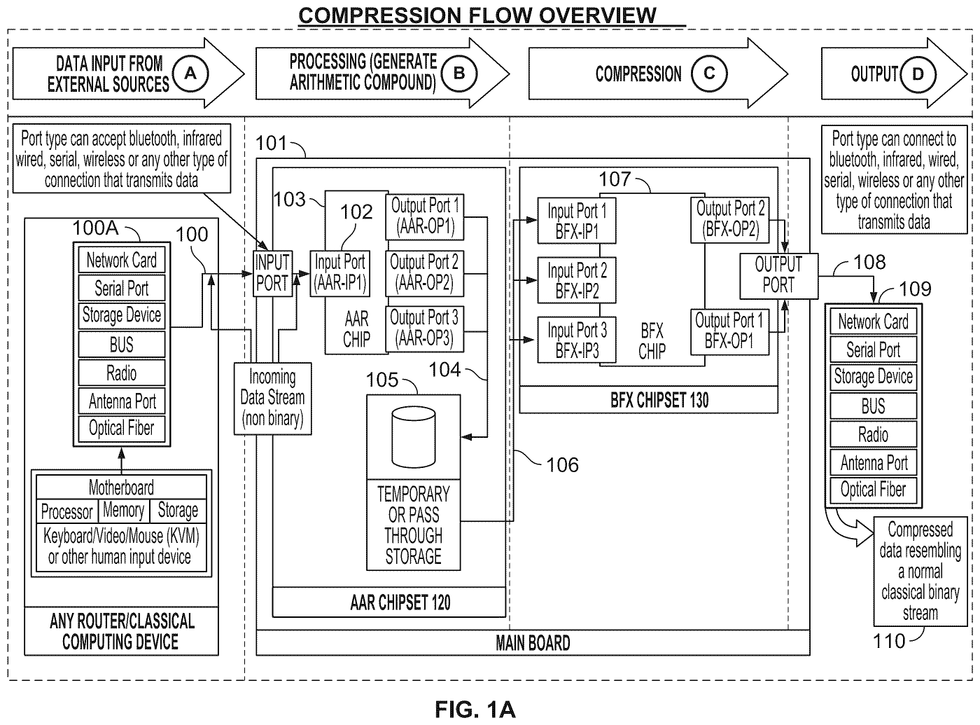

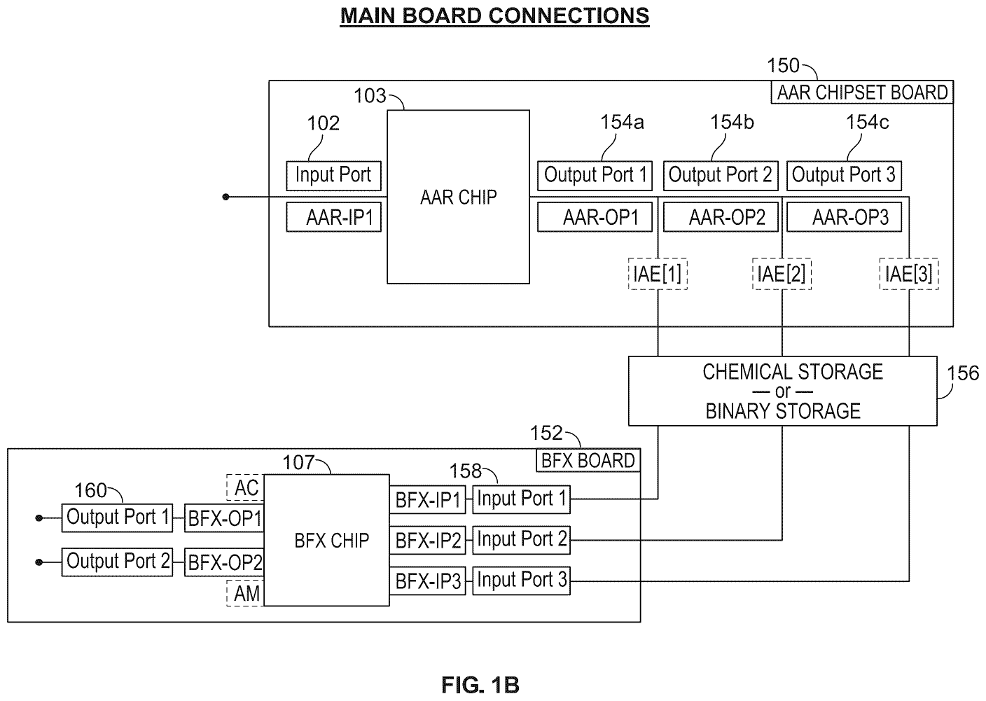

The present disclosure is directed to a superstrate (10) comprising a core body (11), a metal-free electrically conductive layer overlying the core body (12), and a capping layer including a fluoropolymer (13) directly overlying the electrically conductive layer (12), see illustration in FIG. 1. In one aspect, both the electrically conductive layer (12) and the capping layer (13) can have a UV-transparency at 365 nm of at least 80%.

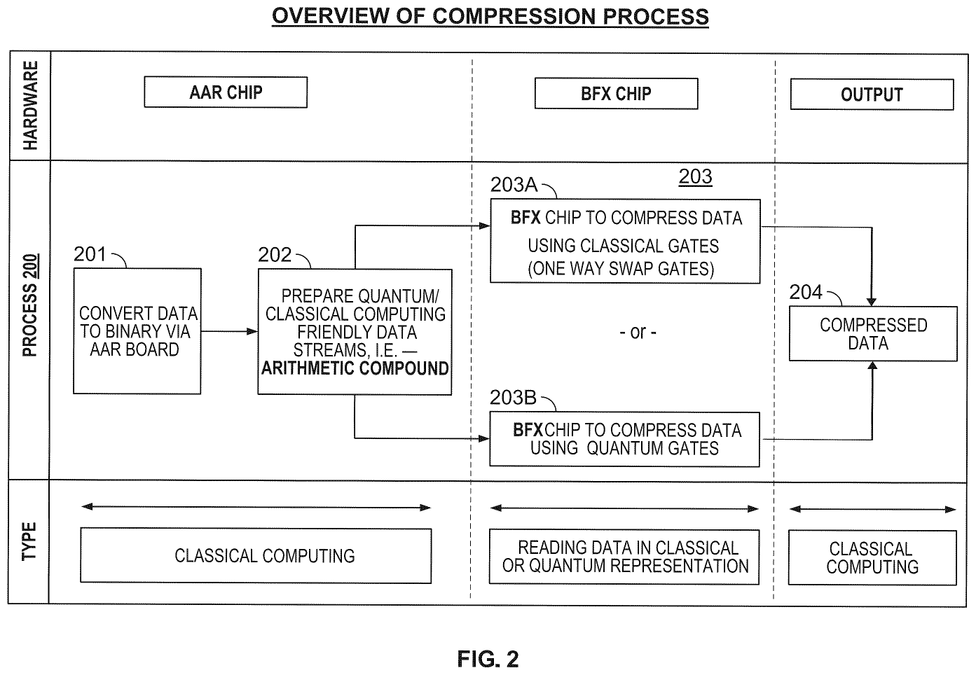

In one embodiment, forming the superstrate of the present disclosure can be conducted by the following steps: (21) providing a core body having a first surface and a second surface, the first surface being opposite to the second surface; and (22) applying on the first surface of the core body a liquid layer of a coating composition, and solidifying the coating composition to form an electrically conductive layer, wherein the coating composition can comprise an electrically conductive polymer and a dopant. In the following step (23), a protective coating composition can be applied directly on the electrically conductive layer to form a capping layer, wherein the protective coating composition can include a fluoropolymer (see also FIG. 2).

In one embodiment, both the coating composition for forming the electrically conductive layer and the protective coating compositions for forming the capping layer can be applied by spin-coating. Applying the coating composition is not limited to spin-coating. In another aspect, the coating composition can be applied by dip-coating, or via a dispenser by drop-coating.

The coating composition for forming the electrically conductive layer can comprise an electrically conductive polymer. One aspect for the selecting the electrically conductive polymer is a desired high UV transparency after forming a solid layer. In a particular aspect the electrically conductive layer can have a UV transparence at 365 nm of at least 82%, or at least 85%, at least 90%, or at least 95%.

Non-limiting examples of electrically conductive polymers can be a polyacetylene, a polypyrrole, a polythiophene, a poly(3-alkylthiophene), a polyphenylene sulfide, a polyphenylenevinylene, a polythienylenevinylene, a polyphenylene, a polyisothianaphthene, a polyazulene, a polyfuran, or a polyaniline, or any combination thereof.

In a particular aspect, the conductive polymer can be a polythiophene or a polyphenylene. In a certain particular aspect, the conductive polymer can include poly(3,4-ethylenedioxythiophene) (PEDOT).

In addition to the conductive polymer, the electrically conductive layer can further include a dopant. The dopant can largely increase the electrical conductivity of a conductive polymer. The dopant can be an inorganic dopant or an organic dopant. Non-limiting examples of dopants suitable for the present disclosure can be small ionic polymers, for example polystyrene sulfonate (PSS), or inorganic materials, such as I₂, Br₂, BF₄⁻, or ClO₄⁻.

The amount of the dopant can be at least 1 wt % based on the total weight of conductive polymer and dopant, such as at 5 wt %, or at least 10 wt %, or at least 15 wt %, or at least 20 wt %. or at least 25 wt %, or at least 30 wt %. In another aspect, the amount of the dopant may be not greater than 40 wt %, or not greater than 35 wt %, or not greater than 30 wt % based on the total weight of the conductive polymer and the dopant.

In one embodiment, the coating composition for forming the electrically conductive layer can be a dispersion comprising an electrically conductive polymer, a dopant and a solvent. In a particular aspect, the solvent can be water.

The amount of electrically conductive polymer and dopant in the coating composition can be at least 0.5 wt % based on the total weight of the coating composition, or at least 1 wt %, or at least 1.2 wt %, or at least 1.5 wt %. or at least 2 wt %. In another aspect, the amount of electrically conductive polymer and dopant may be not greater than 20 wt %, or not greater than 15 wt %, or not greater than 10 wt %, of not greater than 5 wt %, or not greater than 3 wt %.

In order to apply the coating composition by spin-coating, the viscosity of the coating composition at 23° C. may be not greater than 500 mPa·s, or not greater than 300 mPa·s, or not greater than 100 mPa·s, or not greater than 50 mPa·s, or not greater than 25 mPa·s, or not greater than 20 mPa·s, or not greater than 15 mPa·s, or not greater than 12 mPa-s, or not greater than 10 mPa·s. In another aspect, the coating composition can have a viscosity of at least 2 mPa·s, or at least 4 mPa·s, or at least 6 mPa-s.

After applying the coating composition, the solvent can be removed by drying. In aspects, drying can be conducted on a hot-plate, or in an oven, or via IR-radiation.

In a certain aspect, the drying temperature and drying time may be varied in order to obtain the highest possible electrical conductivity of the formed electrically conductive layer. It has been surprisingly observed that the electrical conductivity of the conductive layer can be influenced by the drying time. It was observed that a maximum of the electrical conductivity can be reached after a certain drying time (called herein also maximum drying time (DTₘₐₓ), and that the electrical conductivity decreases if drying is continued after reaching DTₘₐₓ. Accordingly, in one aspect of the method, preliminary experiments can be conducted to determine DTₘₐₓ at a given temperature in relation to the electrical conductivity of the formed conductive layer.

The material of the core body of the superstrate onto which the coating composition is applied can be electrically non-conductive, which means herein having an electrical conductivity of not greater than 10⁻¹⁰ S/m. Non-limiting examples of core-body materials can include a glass-based material, silicon, a spinel, an organic polymer, a siloxane polymer, a fluorocarbon polymer, hardened sapphire, a deposited oxide, an organo-silane, an organosilicate material, inorganic polymers, or any combination thereof. The glass-based material can include soda lime glass, borosilicate glass, alkali-barium silicate glass, quartz glass, aluminosilicate glass, or synthetic fused-silica.

In another embodiment, the amount of coating composition applied onto the core body of the superstrate can be adjusted that a thickness of the formed electrically conductive layer can be at least 40 nm and not greater than 1000 nm. In one aspect, the thickness of the electrically conductive layer can be at least 50 nm, or at least 80 nm, or at least 100 nm, or at least 130 nm, or at least 150 nm, or at least 200 nm. In another aspect, the thickness of the electrically conductive layer may be not greater than 800 nm, or not greater than 500 nm, or not greater than 300 nm, or not greater than 250 nm, or not greater than 200 nm, or not greater than 150 nm. The thickness of the electrically conductive layer can be a value between any of the minimum and maximum values noted above.

As described above, after forming of the electrically conductive layer (21), a capping layer can be formed directly overlying the electrically conductive layer (22). The composition for forming the capping layer, herein also called protective coating composition, can be applied in a similar way as the coating composition for making the conductive layer, for example, by spin-coating or dip-coating. In a particular aspect, the protective coating composition can be applied by spin-coating.

The capping layer can include a fluoropolymer. In a particular aspect, the fluoropolymer can include one of the following structures:

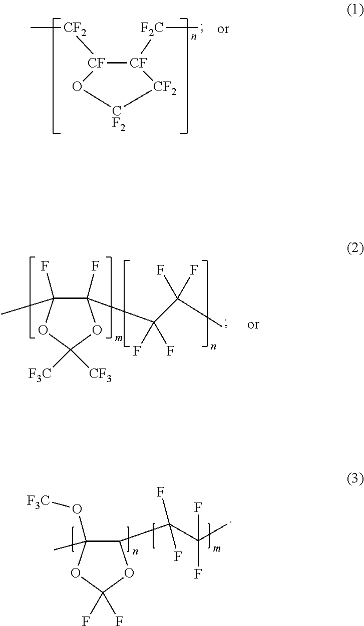

The structures of the above-shown polymers correspond to the commercial products Cytop (1); Teflon AF (2); and Hyflon AD, and are shown as non-limiting examples for fluoropolymers of the capping layer.

In one aspect, the amount of the fluoropolymer in the protective coating composition can be at least 0.5 wt % based on the total weight of the protective coating composition, or at least 1 wt %, or at least 1.5 wt %, or at least 2.0 wt %. In another aspect, the amount of the coating composition may be not greater than 10 wt %, or not greater than 5 wt %, or not greater than 3 wt % based on the total weight of the protective coating composition.

The thickness of the formed capping layer can be at least 40 nm, or at least 50 nm, or at least 80 nm, or at least 100 nm, or at least 120 nm. In another aspect, the thickness of the capping layer may be not greater than 300 nm, or not greater than 250 nm, or not greater than 200 nm, or not greater than 150 nm, or not greater than 130 nm. In a particular aspect, the thickness of the capping layer may be at least 40 nm and not greater than 150 nm.

In one aspect, the capping layer can consist essentially of the fluoropolymer. As used herein, consisting essentially of the fluoropolymer means that the amount of fluoropolymer is at least 95 wt % based on the total weight of the capping layer.

The capping layer can have an amorphous structure, which makes it possible to be highly UV-transmissive and to contain a certain porosity and thereby being gas permeable. In one aspect, the capping layer can have a helium gas permeability of at least 10⁻⁸ cm³·cm/cm²·s·cm Hg.

Similarly as the electrically conductive layer, for good functioning of the superstrate, a UV transparence of the capping layer should be at least 80%, or at least 85%, or at least 90%.

It has been surprisingly found that the capping layer can increase the electrical conductivity of the underlying electrically conductive layer. In one aspect, the addition of the capping layer can cause an increase of the electrical conductivity of the electrically conductive layer by at least 10% compared to the electrical conductivity of the conductive layer not containing an overlying capping layer. In certain aspects, the increase in electrical conductivity of the conductive layer can be at least 10%, or at least 15%, or at least 20%, or at least 25%, or at least 30%, or at least 35%, or at least 40%.

In another embodiment, the electrical conductivity of the conductive layer can be at least 1 S/m, or at least 5 S/m, or at least 10 S/m, or at least 12 S/m, or at least 14 S/m, or at least 16 S/m, or at least 18 S/m. In another aspect, the electrical conductivity may be not greater than 100 S/m, or not greater than 50 S/m, or not greater than 30 S/m.

In a further embodiment, the thickness ratio of the thickness of the electrically conductive layer to the thickness of the capping layer can range from 1:1 to 30:1, or from 1:1 to 20:1, or from 1:1 to 1:10, or from 1:1 to 1:5, or from 1:1 to 1:3.

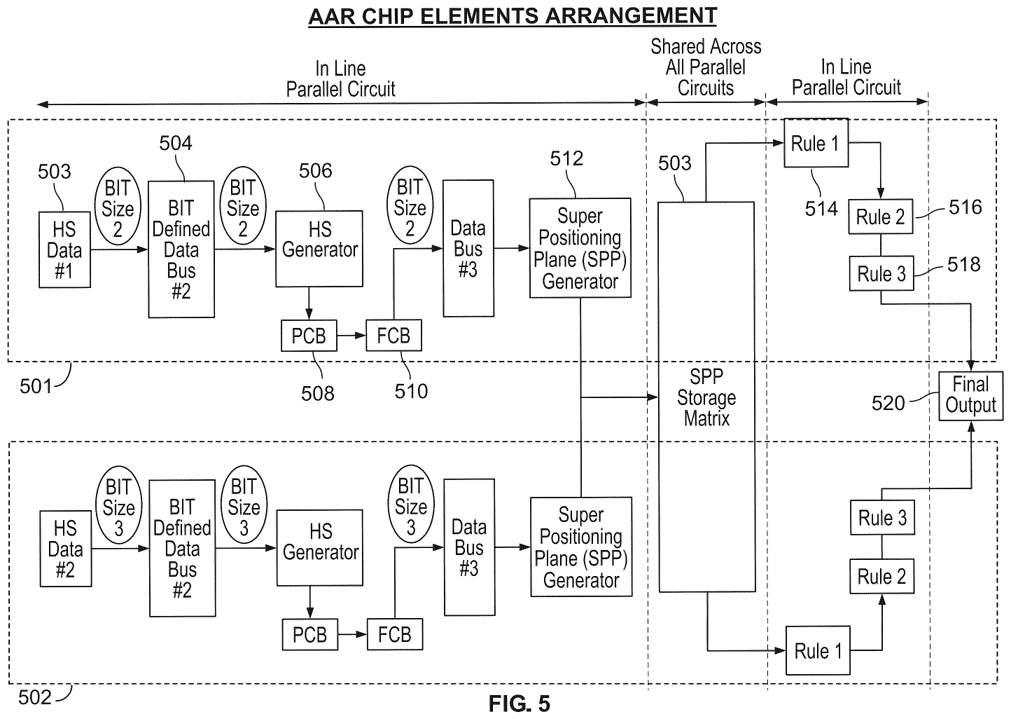

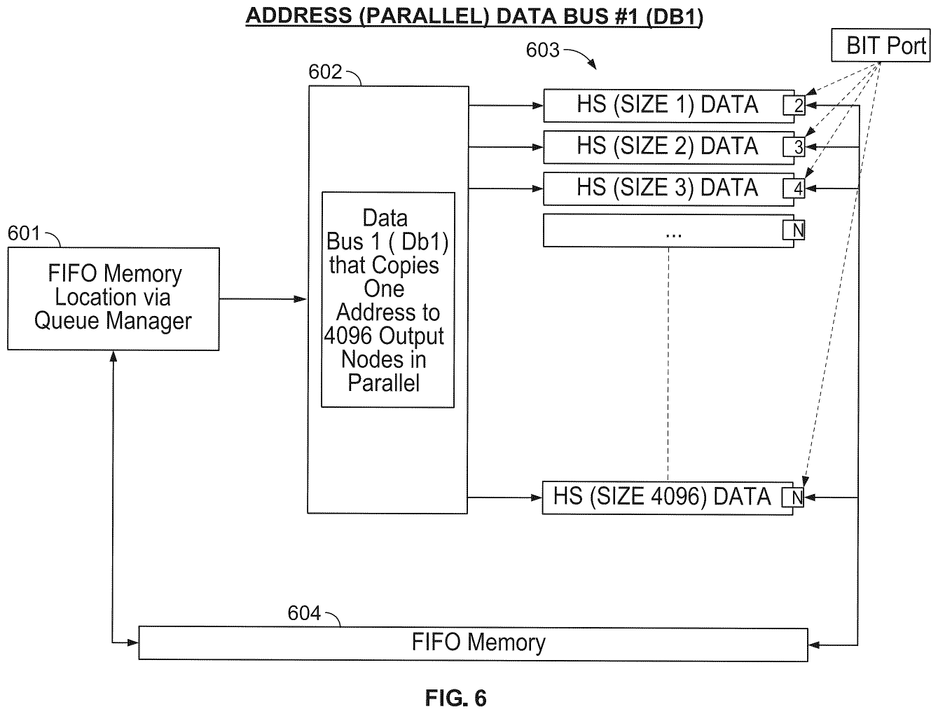

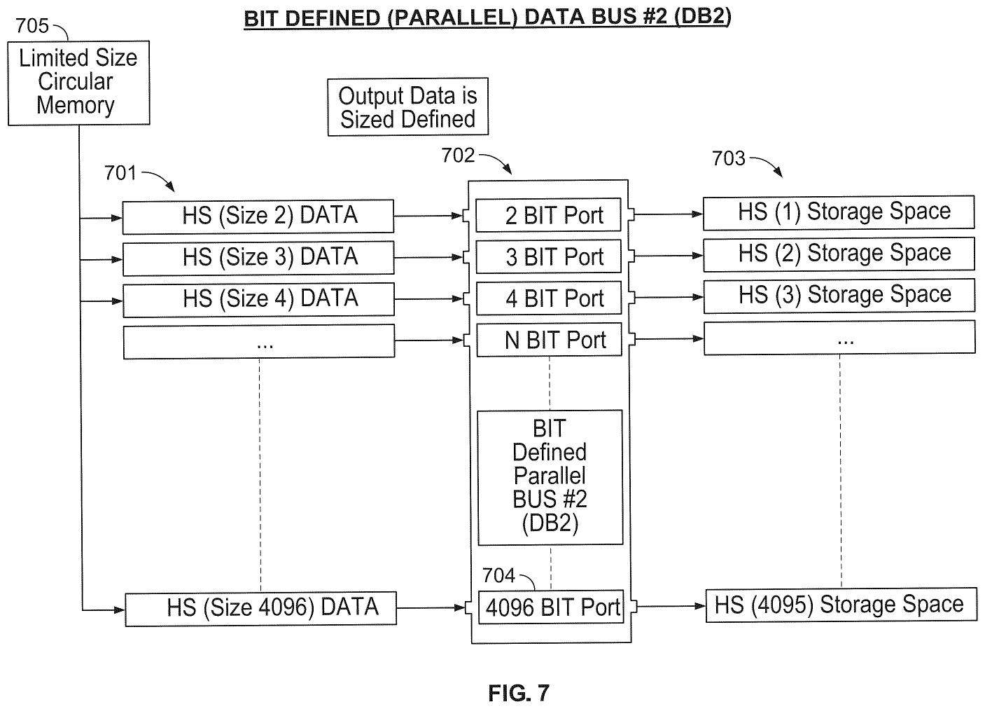

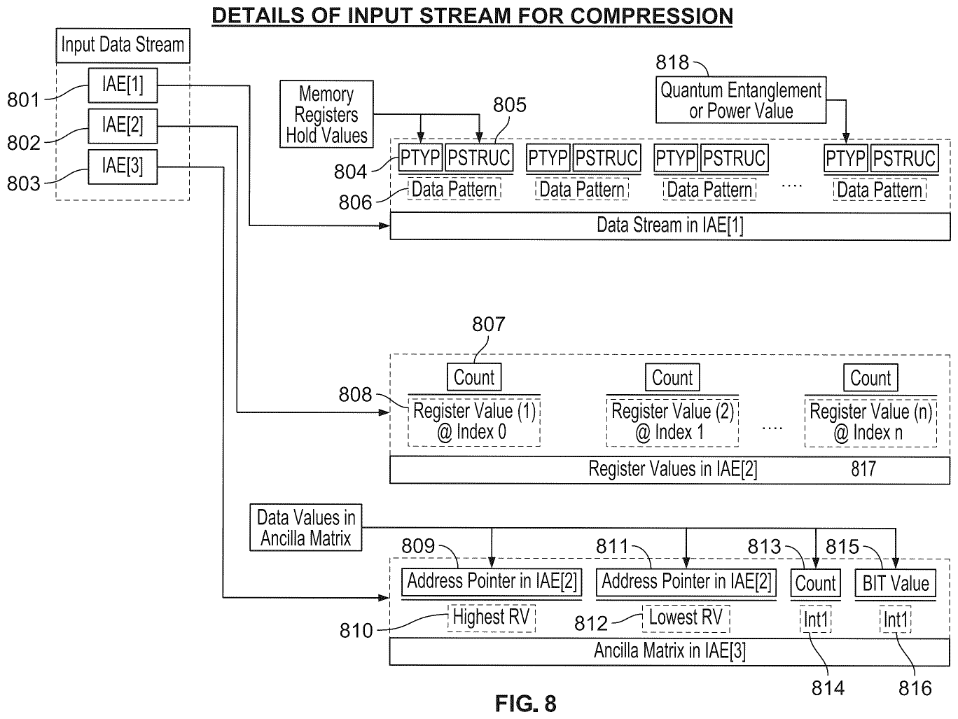

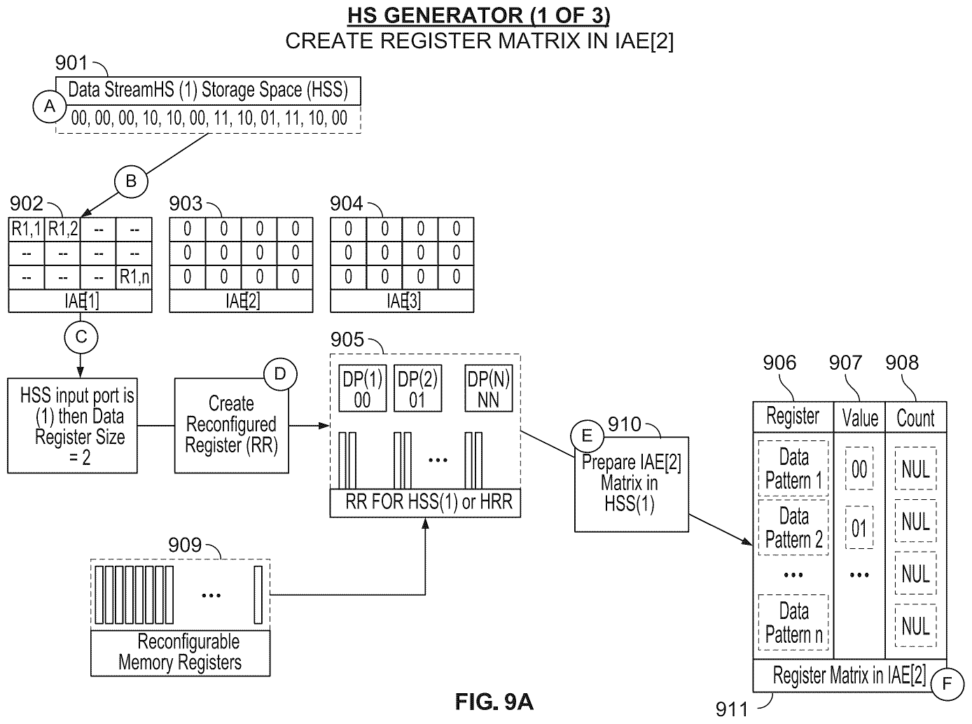

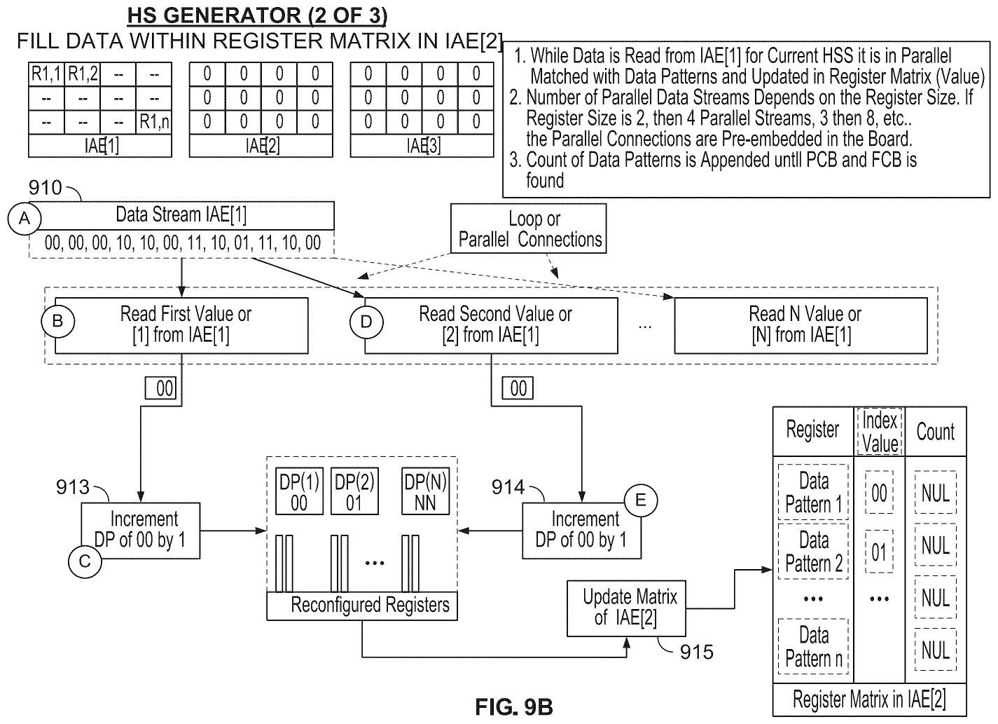

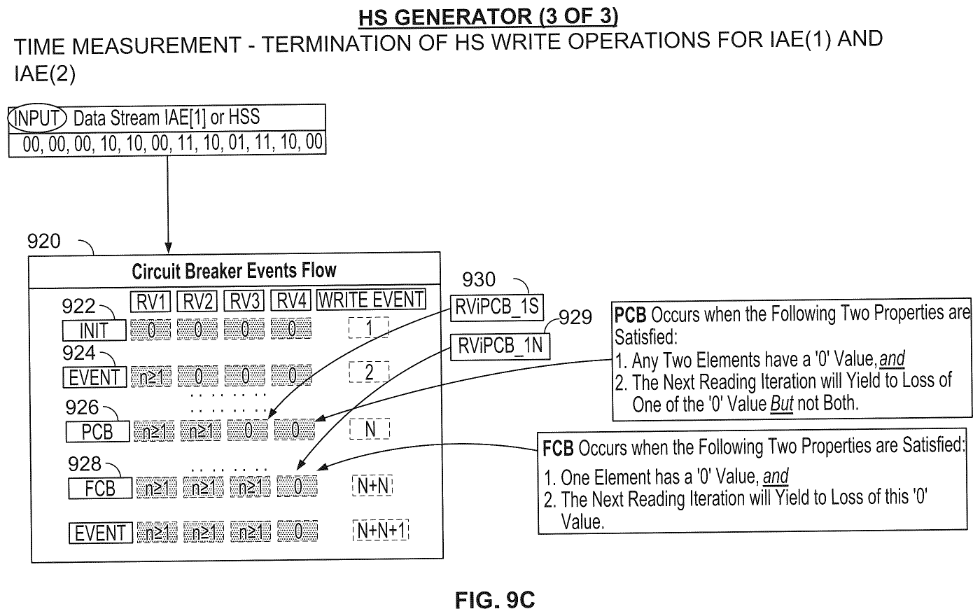

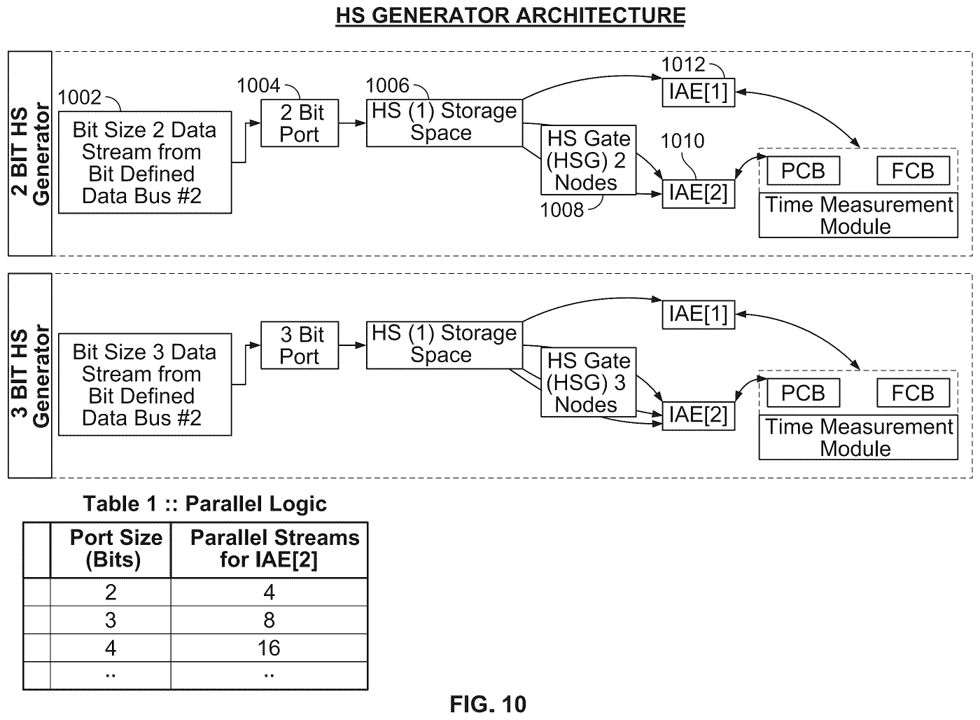

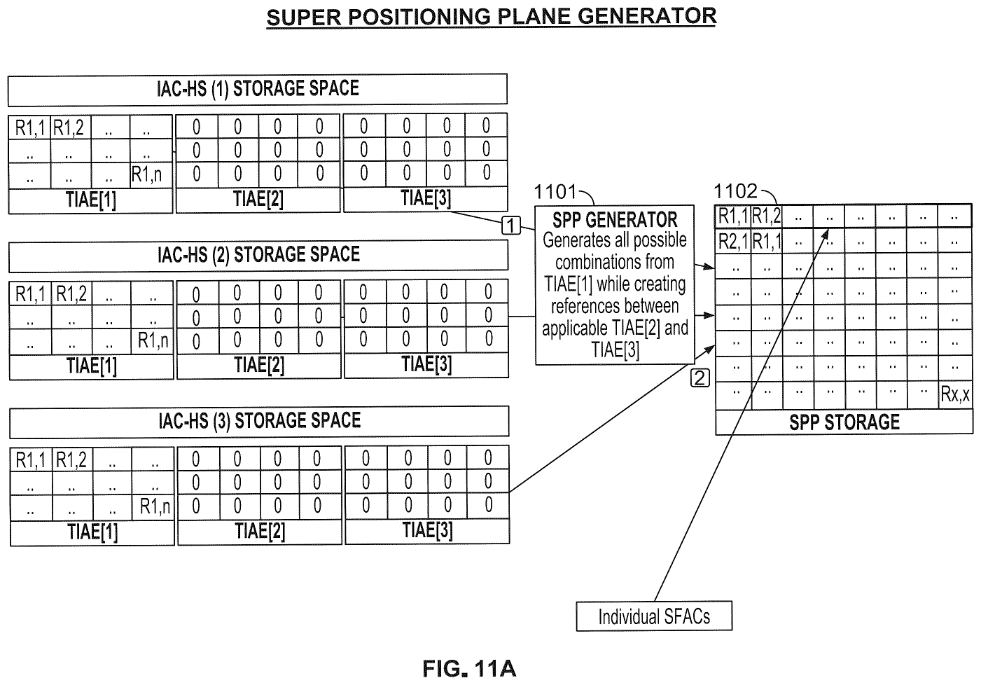

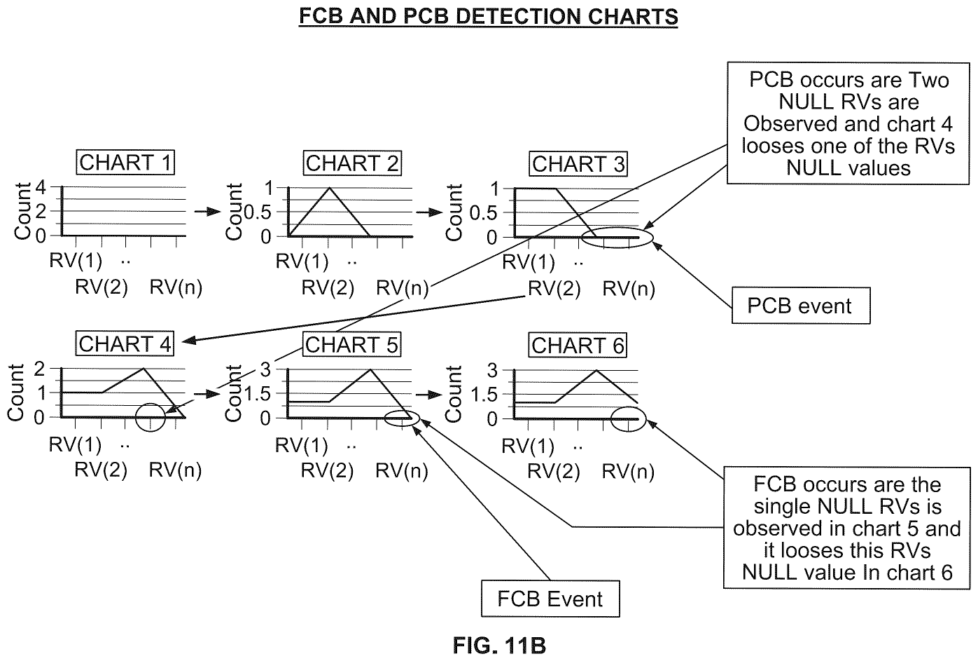

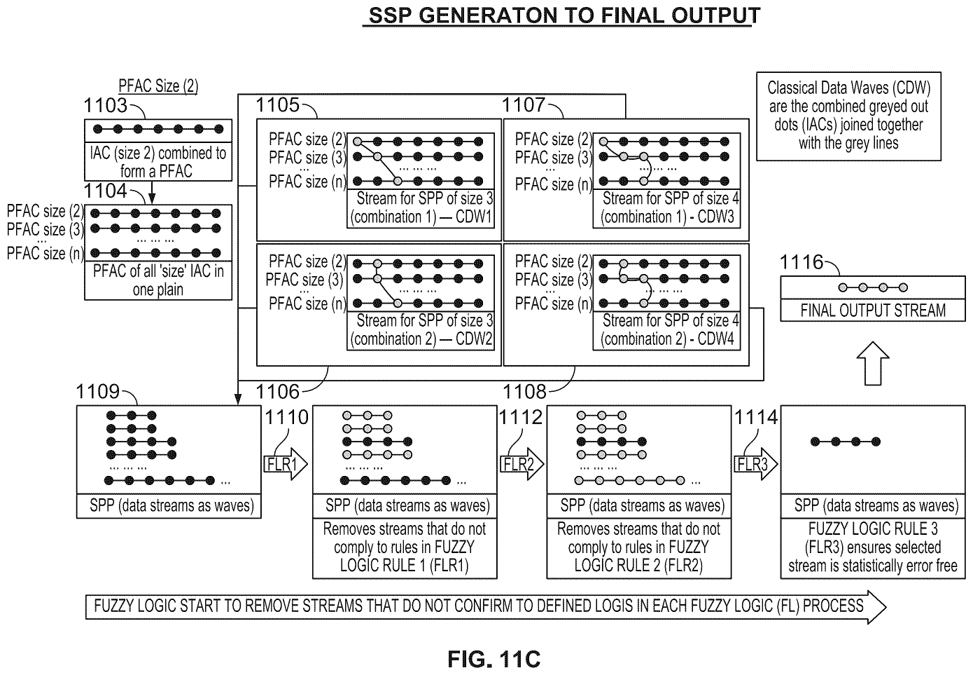

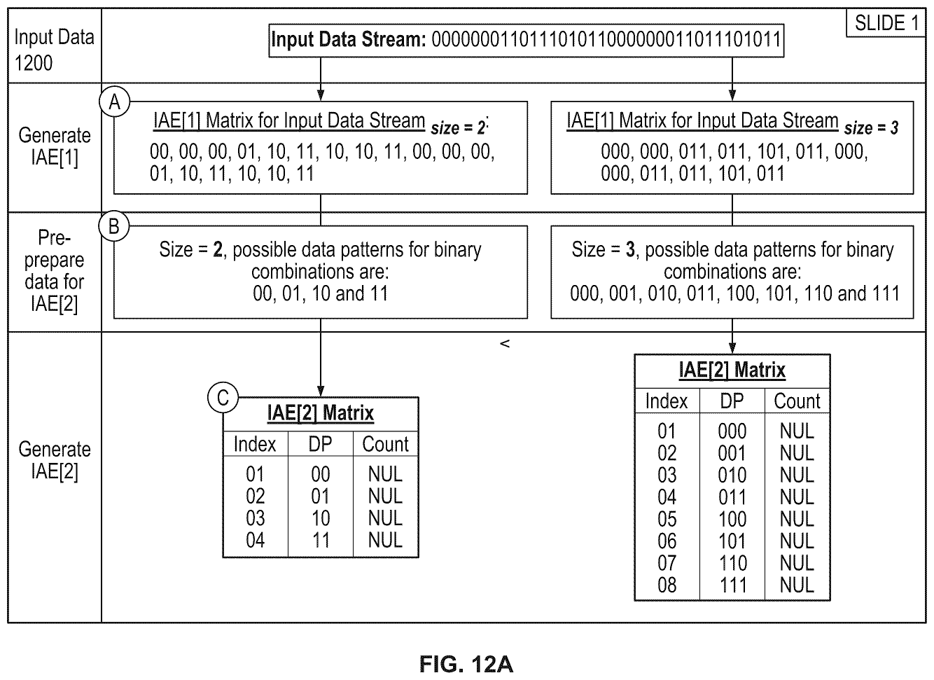

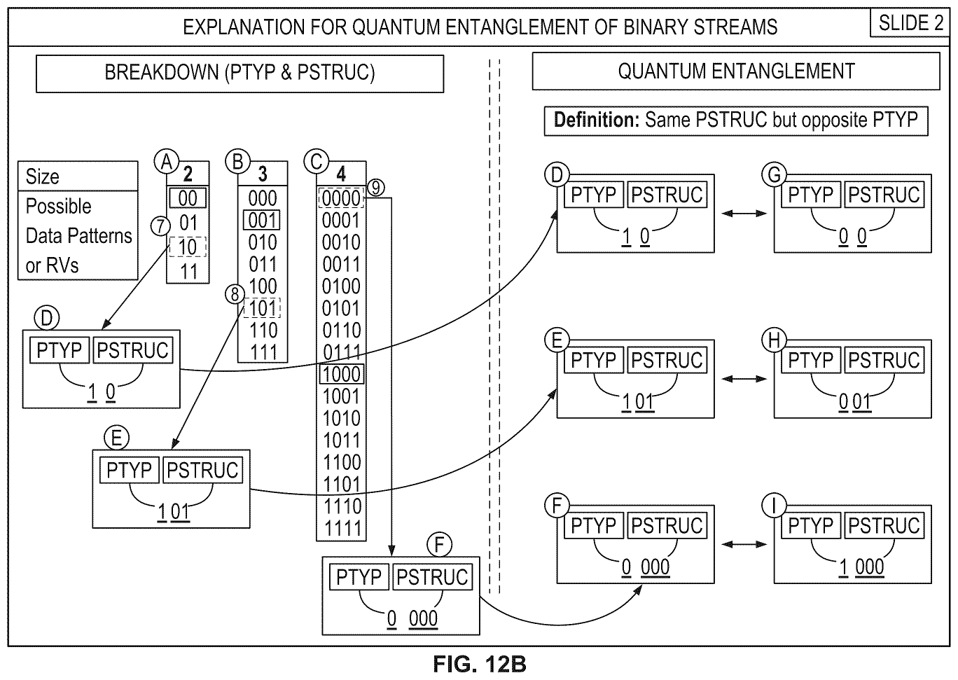

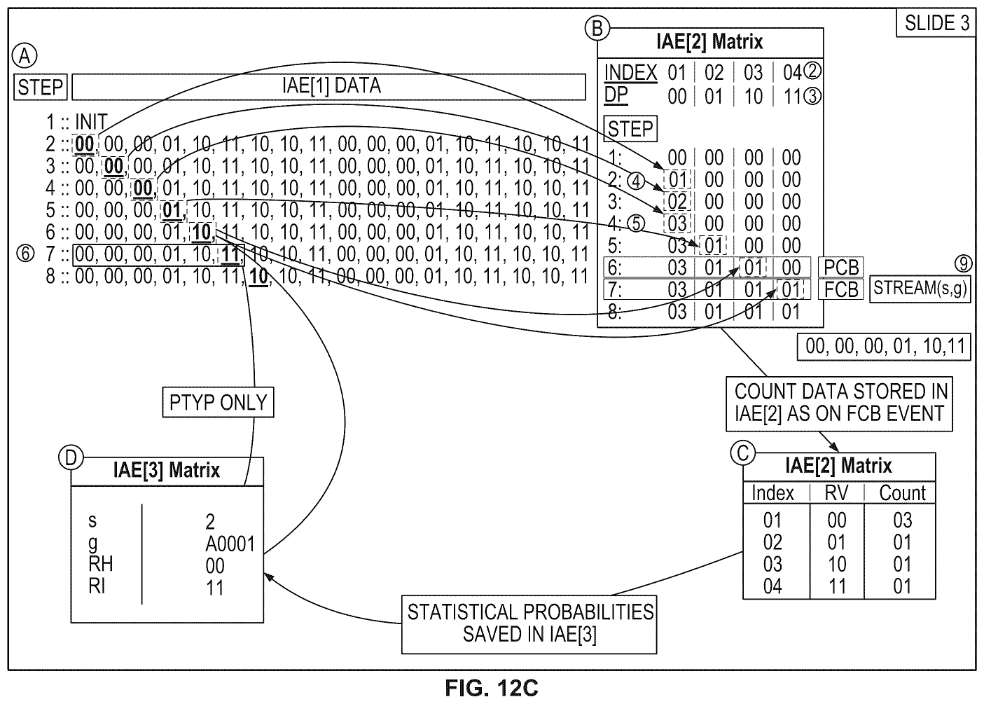

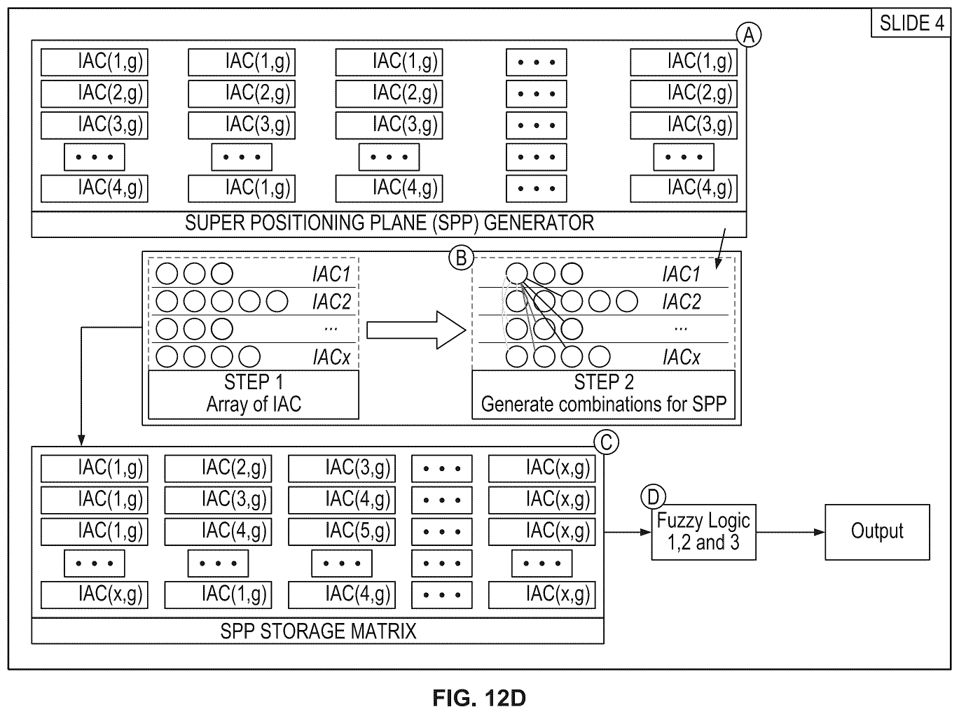

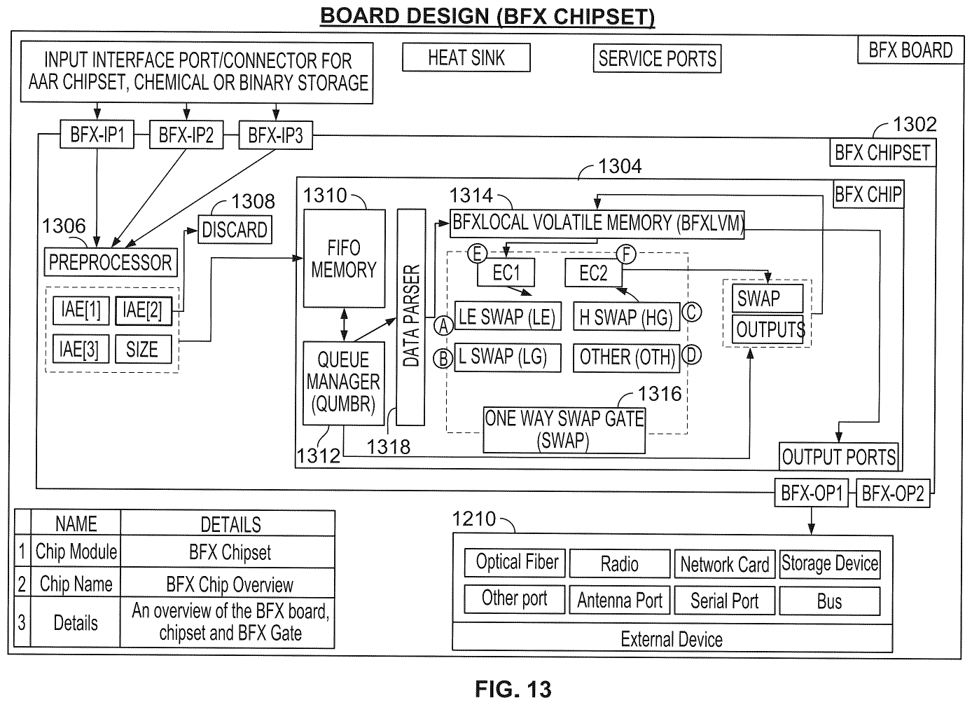

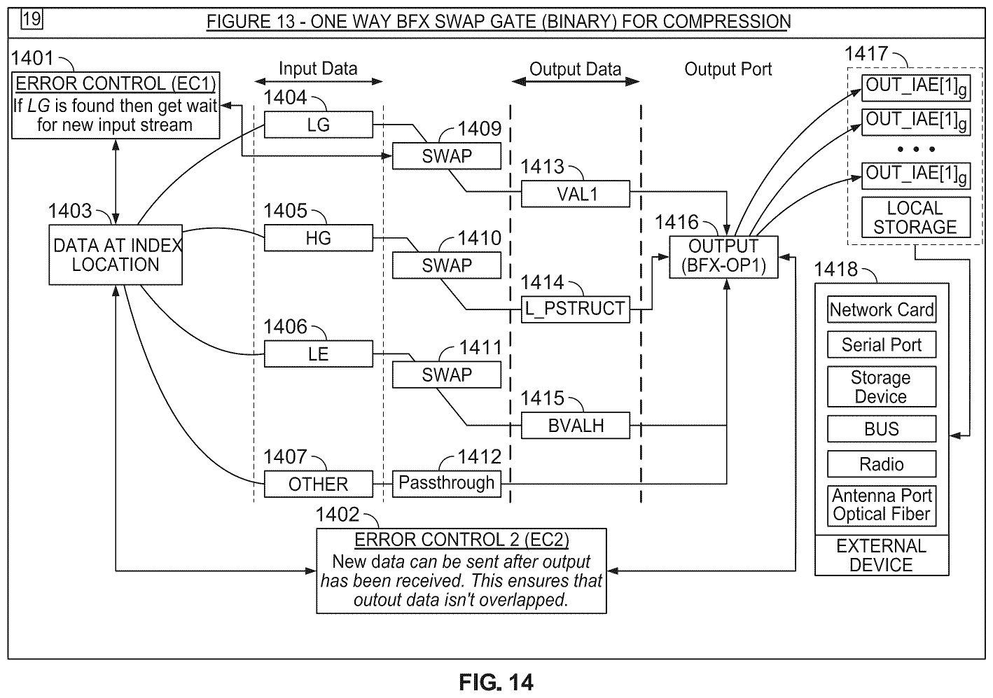

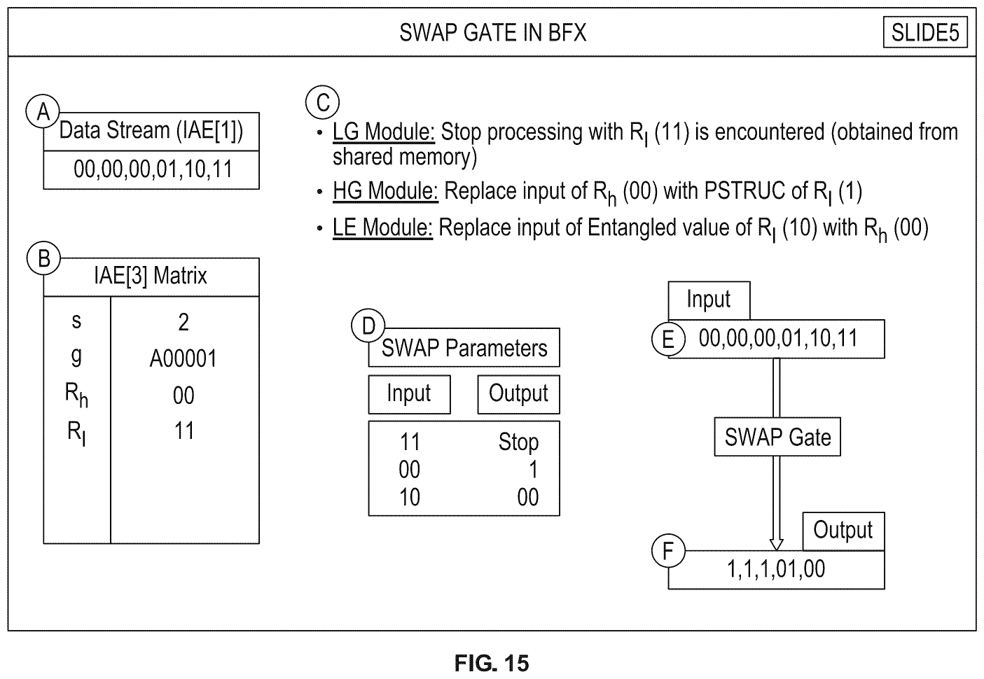

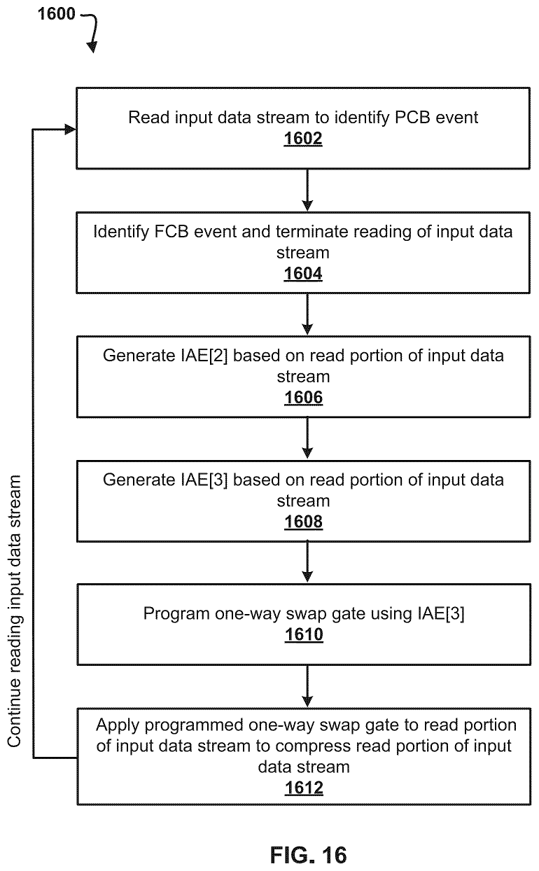

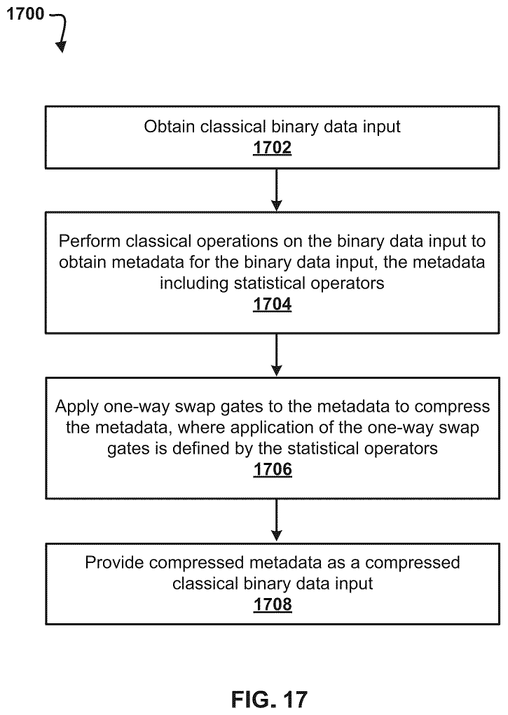

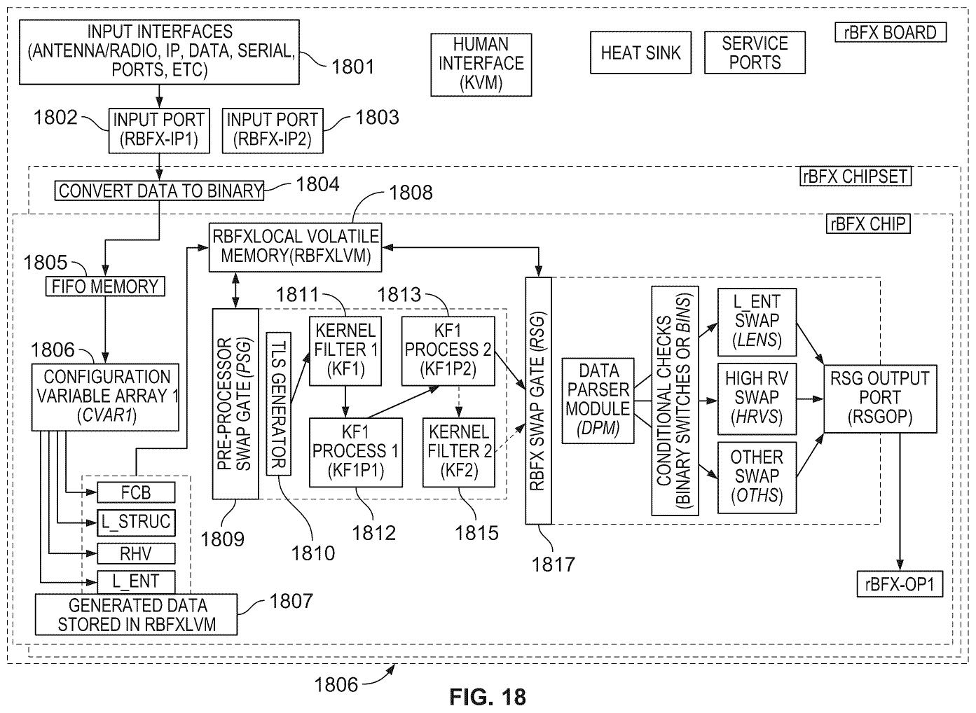

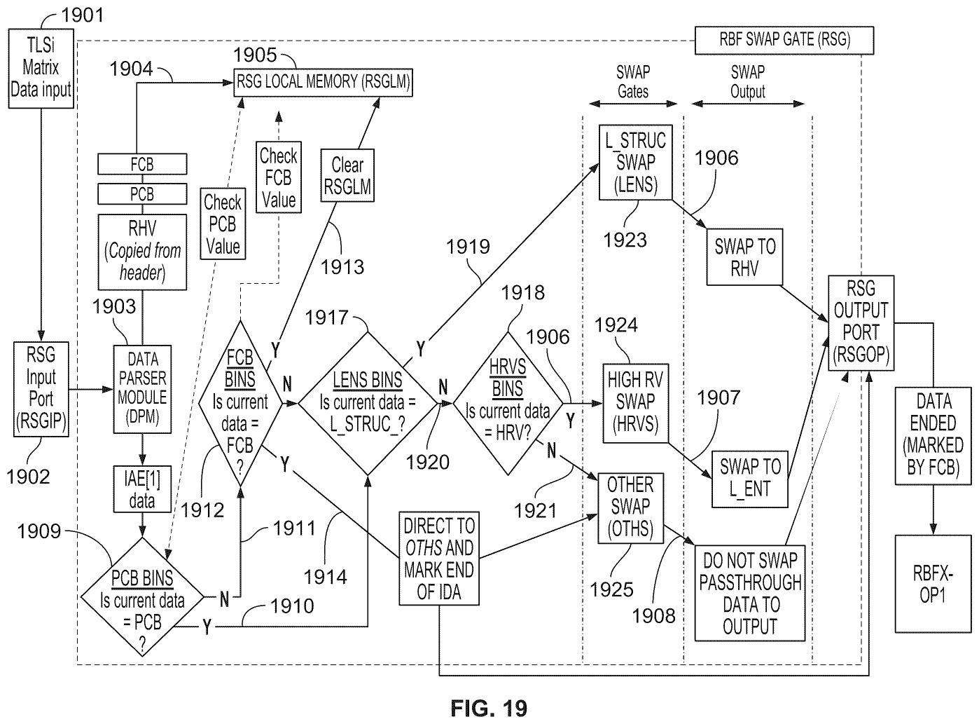

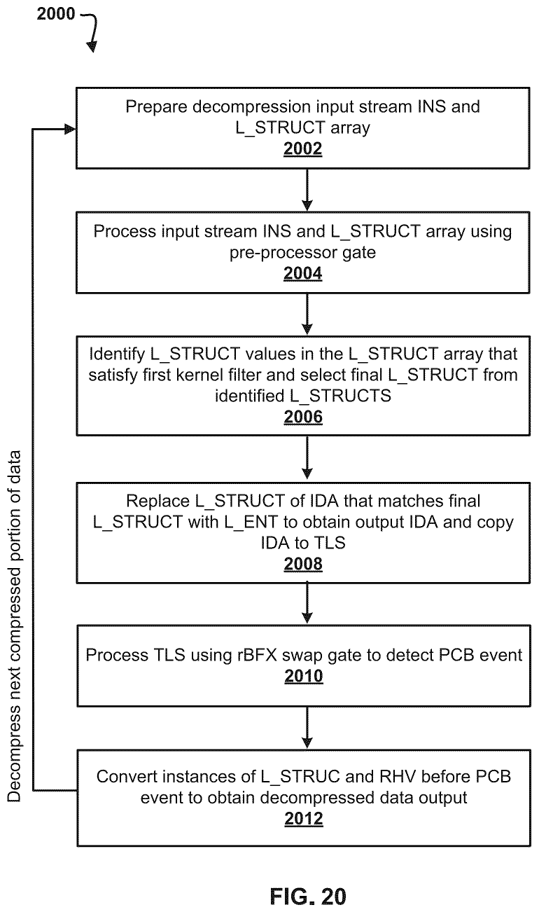

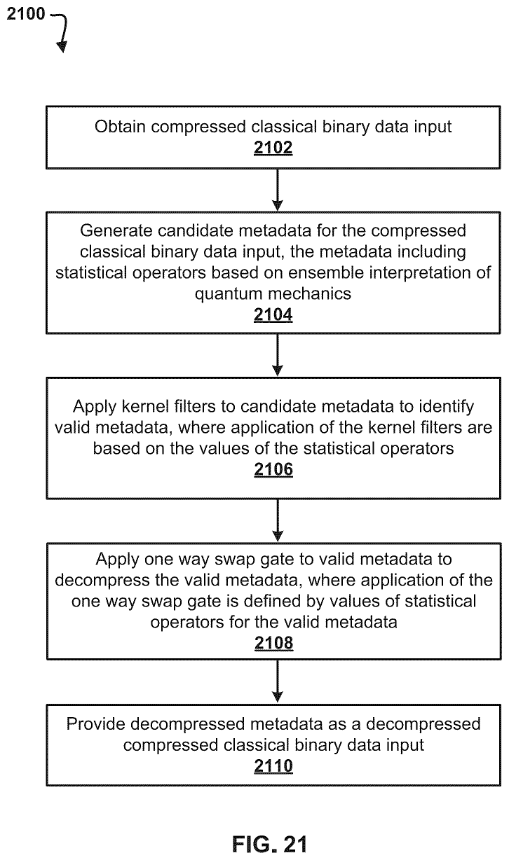

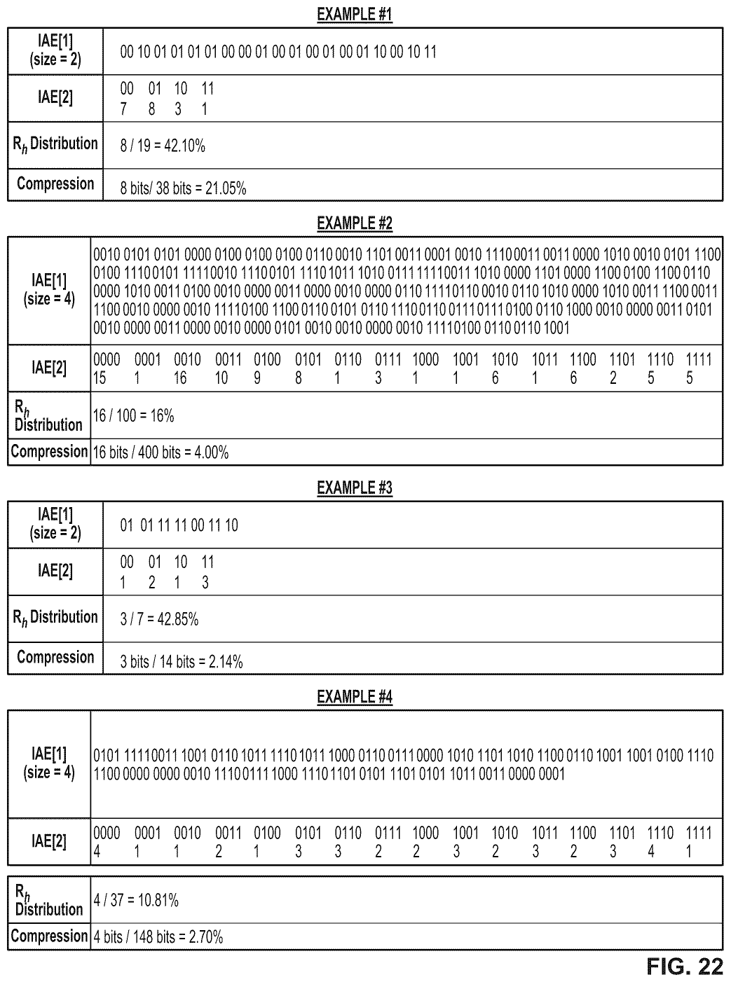

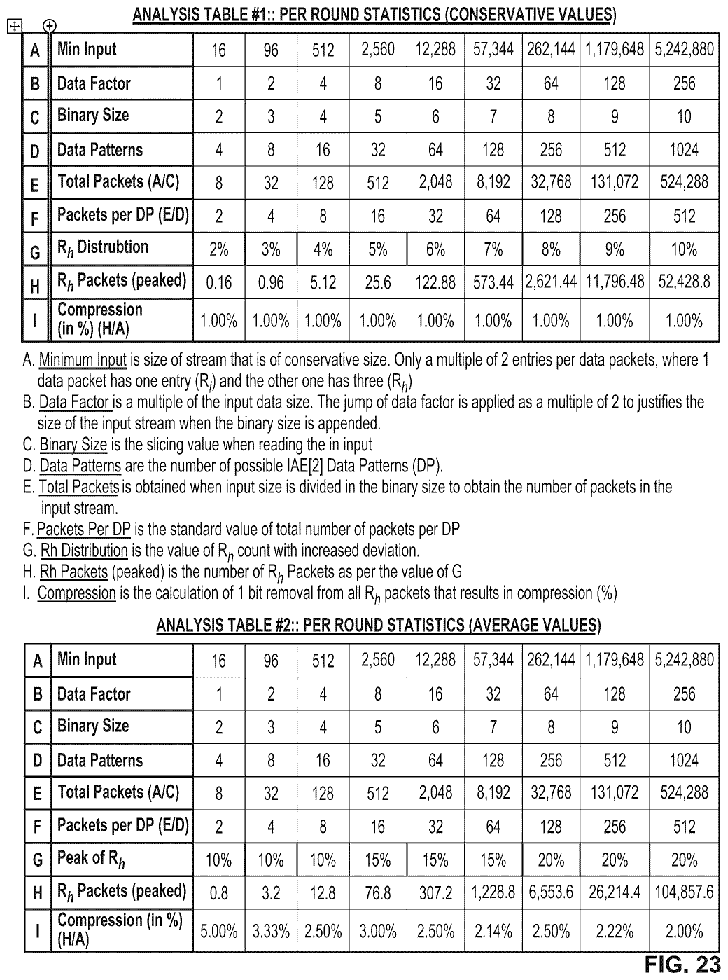

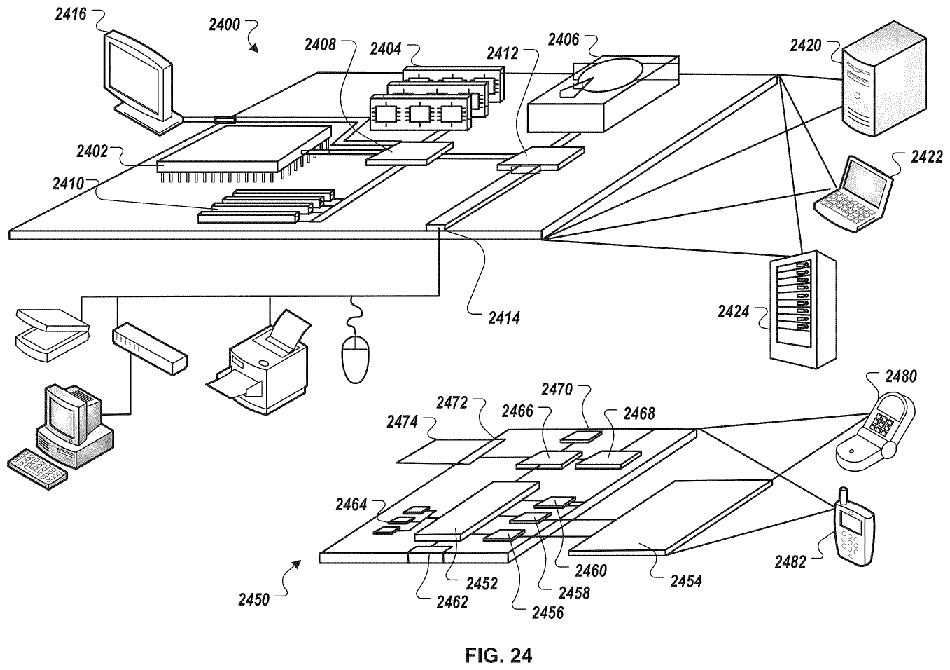

Referring to FIG. 5, an apparatus (50) in accordance with an embodiment described herein can be used to planarize a substrate (52) using a superstrate (58) of the present disclosure. The superstrate (58) can be positioned spaced-apart from the substrate (52).

The substrate (52) may be a semiconductor base material, such as a silicon wafer, but may include an insulating base material, such as glass, sapphire, spinel, or the like. The substrate (52) may be coupled to a substrate holder (54), for example, to a chuck. The chuck may be any chuck including vacuum, pin-type, groove-type, electrostatic, electromagnetic, or the like. The substrate (52) and substrate holder (54) may be further supported by a stage (56). The stage (56) may provide translating or rotational motion along the X-, Y-, or Z-directions.

The superstrate (58) can be used to planarize a formable material deposited on a substrate (52). The superstrate (58) can be coupled to a superstrate holder (59). The superstrate (58) may be both held by and its shape modulated by the superstrate holder (59). The superstrate holder (59) may be configured to hold the superstrate (58) within a chucking region. The superstrate holder (59) can be configured as vacuum, pin-type, groove-type, electrostatic, electromagnetic, or another similar holder type. In one embodiment, the superstrate holder (59) can include a transparent window within the body of the superstrate holder (59).

The apparatus (50) can further include a fluid dispense system (51) for depositing a formable material (53) on the surface of the substrate (52). The formable material (53) can be positioned on the substrate (52) in one or more layers using techniques such as droplet dispense, spin-coating, dip coating, chemical vapor deposition (CVD), physical vapor deposition (PVD), thin film deposition, thick film deposition, or combinations thereof. The formable material (53) can be dispensed upon the substrate (52) before or after a desired volume is defined between the superstrate (58) and the substrate (52). The formable material (53) can include one or more polymerizable monomers and/or oligomers and/or polymers that can be cured using actinic radiation and/or heat.

The present disclosure is further directed to a method of manufacturing an article. The method can comprise applying a layer of a formable material on a substrate; bringing the layer of the formable material into contact with the superstrate of the present disclosure; and curing the formable material with light or heat to form a cured layer. The substrate and the cured layer may be subjected to additional processing to form a desired article, for example, by including an etching process to transfer an image into the substrate that corresponds to the pattern in one or both of the solidified layer and/or patterned layers that are underneath the solidified layer. The substrate can be further subjected to known steps and processes for device (article) fabrication, including, for example, curing, oxidation, layer formation, deposition, doping, planarization, etching, formable material removal, dicing, bonding, and packaging, and the like. In a certain aspect, the substrate may be processed to produce a plurality of articles.

The cured layer may be further used as an interlayer insulating film of a semiconductor device, such as LSI, system LSI, DRAM, SDRAM, RDRAM, or D-RDRAM, or as a resist film used in a semiconductor manufacturing process.

### EXAMPLES

The following non-limiting examples illustrate the concepts as described herein.

### Example 1

Glass slides with the dimensions of 1 inch×3 inches and a thickness of 1.2 mm (from VWR, code 16004-424) were used as substrates (herein also called core-body) to mimic the core body of the superstrate. Before applying the coating layers, the glass slides were subjected to a cleaning procedure by washing them with an aqueous detergent solution, followed by washing with isopropylalcohol (IPA) and drying under nitrogen. Thereafter, the glass slides were placed in an UV ozone cleaner for 5 minutes to activate the surface.

For the forming of the electrically conductive layers, an aqueous coating composition was prepared containing 1.3 wt % PEDOT:PSS (from Sigma Aldrich, code 483095).

The coating composition was applied by spin-coating using a Brewer Science Cee(R)300X spin coater with a 2 square inches size spin chuck. The glass slide was placed in the center of the spin chuck and the coating composition was applied under the following spinning regime: Step 1: 200 rpm with an acceleration rate of 200 rpm/s for six seconds; Step 2: 800 rpm with an acceleration rate of 200 rpm/s for 40 seconds. After the spin-coating, the coated slide was moved to a hot plate having a temperature of 135° C. and baked for 5 or 10 minutes in order to remove the water and to form a solid electrically conductive layer, herein also called electrically conductive layer or PEDOT:PSS layer. The thickness of the PEDOT:PSS layer after drying was 127 nm, measured with an ellipsometer (JA Woollam Spectroscopic Ellipsometer M-2000 X-210).

After forming the PEDOT:PSS layer, in certain embodiments, a capping layer containing the fluoropolymer Cytop® (see structure of formula 1) was applied directly on top of the PEDOT:PSS layer. The protective coating composition for forming the capping layer was made containing 2 wt % of Cytop CTL-809A in solvent FC-43 from 3M.

The protective coating composition for forming the capping layer was spin-coated on the glass-slides directly above the previously formed PEDOT-PSS layer. The spin-coating of the capping layer was applied using the following spinning regime: Step 1: 500 rpm with an acceleration rate of 1000 rpm/s for 10 seconds; Step 2: 1000 rpm with an acceleration rate of 3000 rpm/s for 60 seconds; Step 3: 3000 rpm with an acceleration rate of 3000 rpm/s for 30 seconds. After the spin-coating, the slide was moved to the hot plate which was set to a temperature of 120° C. and baked for 5 minutes. After drying and solidifying, the thickness of the capping layer was 96 nm (measured with the ellipsometer).

### Electrical Conductivity Comparisons

### Measurement of the Electrical Conductivity:

The electrical conductivities of the formed conductive layers were measured using an SR715 LCR Meter coupled with a Fluke hand-held DC voltage meter with rigid probes. The rigid probes were connected to two copper pads, wherein each copper pad had a size of 2.54 cm×1 cm. Before the measurements, the copper pads were polished with a 2000 grit sandpaper to remove any formed oxide and other contaminants.

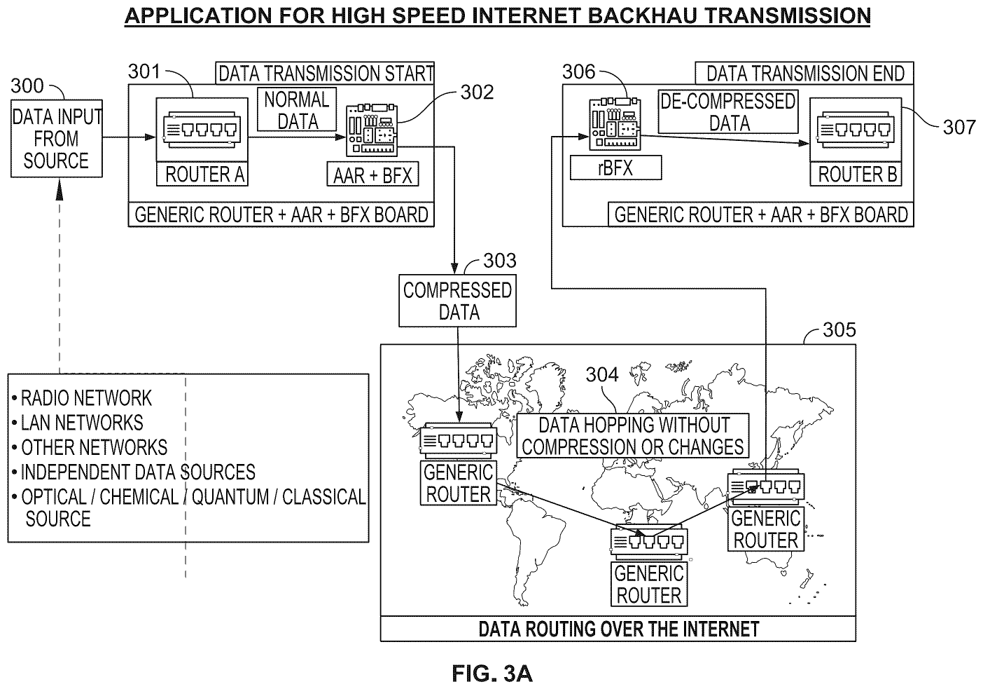

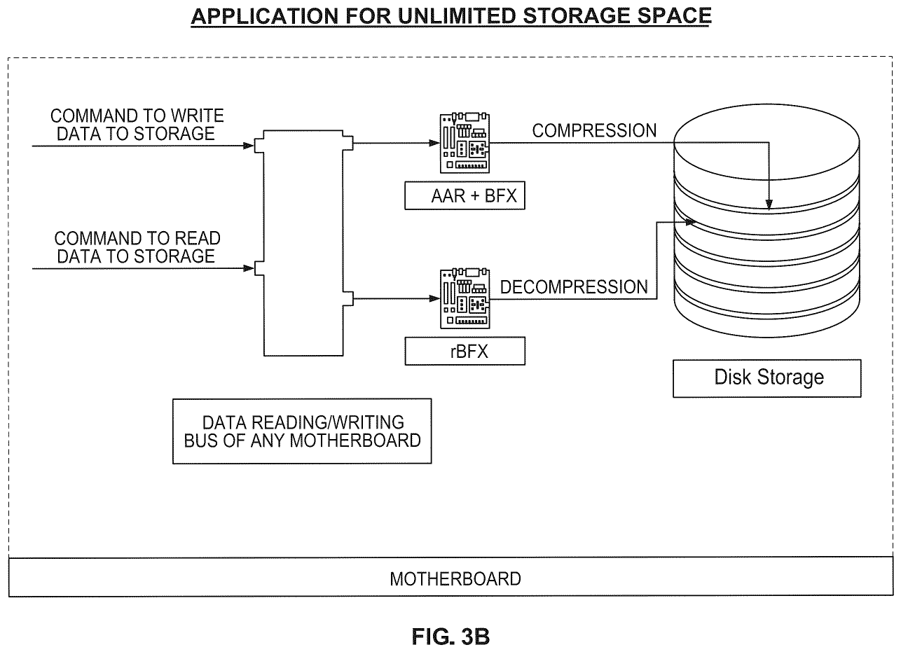

For the measurement, as illustrated in FIG. 3, the coated glass slide (31) was placed on a grid paper (not shown) and the two copper pads (P1, P2) were placed parallel to each other on the outer coating surface of the glass slide (31). After positioning the two copper pads in a defined distance L to each other, rigid probes (not shown) were attached to the copper pads (P1, P2) and the electrical resistivity (R) was measured. The distance between the two copper pads was varied during a series of measurements and recorded each time as (L).

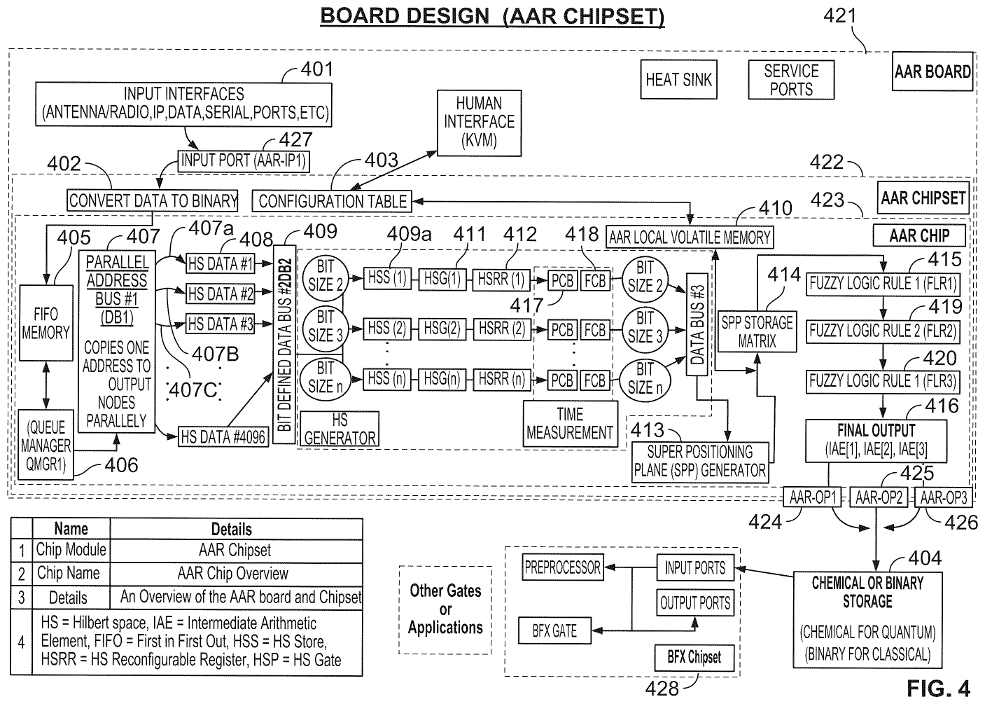

For determining the electrical conductivity data points for a linear curve were obtained by measuring the resistance at different distances (L) of the copper pads to each other. The used distances (L) were 1 cm, 2 cm, 3 cm, 4 cm, and 5 cm. For the curves shown in FIG. 4, the measured Resistance was plotted against L/A, wherein A was the area of the cross-section of the electrically conductive layer (0.0000127 cm thickness×2.5 cm width).

From each graph, the electrical conductivity was obtained from the slope L/A vs. R according to equation (1): σ (S/m)=1/ρ=L/(R×A)=(L/A)/R (eq. 1), with σ being the electrical conductivity, L being the distance between two probes of the multimeter, A being the area of the cross-section of the film; R being the measured resistance.

FIG. 4 shows a comparison of four different measurements. Samples S1 and S2 were glass slides containing a 127 nm think PEDOT:PSS coating and directly thereon a 96 nm thick Cytop coating. The difference between S1 and S2 was a different baking time when forming the PEDOT:PSS layer: S1 was baked 5 minutes at 135° C., while S2 was baked 10 minutes at 135° C. The baking time when making the Cytop coating was for both samples 5 minutes.

Comparative samples C1 and C2 shown in FIG. 4 relate to glass slides only coated with a PEDOT:PSS layer, but not containing a capping layer. The difference between C1 and C2 was also the baking time at 135° C., i.e., 5 minutes versus 10 minutes.

A summary of the graphs of FIG. 4 is also shown in Table 1. It can be seen that the measured resistance increased with increasing L/A values. If the capping layer was present (samples S1 and S2), the resistance was always lower in comparison to the respective superstrates which did not contain a capping layer (samples C1 and C2).

TABLE 1

| | | S1 | S2 | C1 | C2 |
|---|---|---|---|---|---|
| | | R [MΩ) | R [MΩ] | R [MΩ] | R [MΩ) |
| L [cm] | L/A | 5 min | 10 min | 5 min | 10 min |
| 1 | 31,000 | 2.04 | 3.10 | 3.15 | 3.35 |
| 2 | 62,000 | 3.34 | 4.70 | 5.15 | 5.90 |
| 3 | 93,000 | 4.55 | 6.20 | 7.03 | 8.00 |
| 4 | 124,000 | 6.03 | 8.00 | 8.95 | 10.42 |
| 5 | 155,000 | 7.45 | 9.90 | 10.92 | 12.40 |

From the slope of the curves for S1, S2, C1, and C2, the electrical conductivities were calculated, which are summarized in Table 2.

TABLE 2

| | S1 | S2 | C1 | C2 |
|---|---|---|---|---|
| | 5 min | 10 min | 5 min | 10 min |
| Electrical | 20 | 15 | 13 | 12 |
| Conductivity [S/m] | | | | |

The electrical conductivity measurements showed that applying the capping layer caused a surprising increase of the electrical conductivity of the PEDOT:PSS layer in comparison to the respective glass slide only containing a PEDOT:PSS layer and no capping layer.

It was further interesting to observe that when baking was conducted for 5 minutes to form the PEDOT:PSS layer, the electrical conductivity increased by 35% after applying the capping layer (20 S/m vs. 13 S/m); but when a longer baking time was conducted (10 minutes instead of 5 minutes), the increase of the electrical conductivity was lower, such as only 20% (15 S/m vs. 12 S/m).

Not being bound to theory, the increase in the electrical conductivity by adding a capping layer including a fluoropolymer might be that the capping layer can provide an additional doping effect. Furthermore, it appears that moderate drying conditions of the conductive layer can be of advantage for a high conductivity increase when applying a capping layer, which may indicate that the type of matrix formed by the conductive polymer/dopant is temperature sensitive and can have an influence on the interaction with the capping layer.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

What is claimed is:

1. A superstrate comprising:
a core body having a first surface and a second surface, the first surface and the second surface being opposite to each other;
an electrically conductive layer directly overlying the first surface of the core body; and
a capping layer directly overlying the electrically conductive layer,
wherein
the core body has an electrical conductivity of not greater than 10⁻¹⁰ S/m;
the electrically conductive layer is metal-free and comprises an electrical conductivity of at least 10⁻⁴ S/m and a UV transparency at 365 nm of at least 80%; and
the capping layer includes a fluoropolymer and has a UV transparency at 365 nm of at least 80%.

2. The superstrate of claim 1, wherein the electrically conductive layer includes an electrically conductive polymer.

3. The superstrate of claim 2, wherein the electrically conductive polymer includes a polyacetylene, a polypyrrole, a polythiophene, a poly(3-alkylthiophene), a polyphenylene sulfide, a polyphenylenevinylene, a polythienylenevinylene, a polyphenylene, or a polyaniline, or any combination thereof.

4. The superstrate of claim 3, wherein the electrically conductive polymer includes a polythiophene, a polyphenylene, or a combination thereof.

5. The superstrate of claim 4, wherein the electrically conductive polymer includes poly(3,4-ethylenedioxythiophene) (PEDOT).

6. The superstrate of claim 2, wherein the electrically conductive layer further includes a dopant.

7. The superstrate of claim 6, wherein an amount of the dopant is at least 1 wt % and not greater than 40 wt % based on the total weight of the conductive polymer and the dopant.

8. The superstrate of claim 6, wherein the dopant includes an ionic polymer.

9. The superstrate of claim 8, wherein the dopant includes a polystyrene sulfonate.

10. The superstrate of claim 9, wherein the electrically conductive layer consists essentially of poly(3,4-ethylenedioxythiophene) (PEDOT) and polystyrene sulfonate (PSS).

11. The superstrate of claim 1, wherein the capping layer is an amorphous layer and has a helium gas permeability of at least 10⁻⁸ cm³·cm/cm²·s·cmHg.

12. The superstrate of claim 1, wherein the fluoropolymer of the capping layer includes a structure of formula (1):

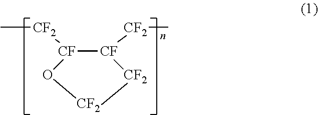

13. The superstrate of claim 1, wherein a thickness of the electrically conductive layer is at least 40 nm and not greater than 1000 nm.

14. The superstrate of claim 13, wherein the thickness of the electrically conductive layer is at least 50 nm and not greater than 200 nm.

15. The superstrate of claim 1, wherein a thickness of the capping layer is at least 20 nm and not greater than 300 nm.

16. The superstrate of claim 15, wherein the thickness of the capping layer is at least 50 nm and not greater than 150 nm.

17. The superstrate of claim 1, wherein a thickness ratio of a thickness of the electrically conductive layer to a thickness of the capping layer ranges from 1:1 to 30:1.

18. The superstrate of claim 1, wherein the electrically conductive layer has an electrical conductivity of at least 14 S/m.

19. A method of forming a superstrate, comprising:
providing a core body having a first surface and a second surface, the first surface being opposite to the second surface;
applying on the first surface of the core body a liquid layer of a coating composition, the coating composition including an electrically conductive polymer and a dopant; solidifying the coating composition to form an electrically conductive layer;
applying a protective coating composition on the electrically conductive layer to form a capping layer, the protective coating composition including a fluoropolymer.

20. The method of claim 19, wherein the conductive polymer and the dopant consist essentially of poly(3,4-ethylenedioxythiophene) (PEDOT) and polystyrene sulfonate (PSS).
